(19) United States
(12) Patent Application Publication
(10) Pub. No.: US 2024/0289093 A1
(43) Pub. Date: Aug. 29, 2024

(54) Entropy Consistency Enhancement for Multi-Channel Entropy Sources

(71) Applicant: SK hynix Inc., Gyeonggi-do (KR)

(72) Inventors: Alexander IVANIUK, Minsk (BY); Siarhei ZALIVAKA, Minsk (BY)

(21) Appl. No.: 18/174,354

(22) Filed: Feb. 24, 2023

(51) Int. Cl. G06F 7/58; H03K 19/21

(52) U.S. Cl. CPC G06F 7/584; H03K 19/21

(57) ABSTRACT

A random number generator and method for generating random numbers. The random number generator has a) a noise source configured to generate M noise bits, and b) an entropy enhancement component (EEC) configured to receive an input sequence of the noise bits from the M sources, process the input sequence of the noise bits, and output a random sequence of bits, wherein the random sequence of bits is more random than the input sequence of the noise bits.

### BACKGROUND

### 1. Field

Embodiments of the present disclosure relate to a random number generation.

### DESCRIPTION OF THE RELATED ART

A common scheme for a National Institute of Standards and Technology (NIST) certified true random number generator (TRNG) consists of an entropy source, a conditioning component, and health tests unit. Together these components can generate sequences of true random numbers with targeted statistical characteristics. The entropy source model itself typically consists of a noise source and a digitalization scheme. The conditioning component is responsible for reducing bias and/or increasing the entropy rate of the resulting output bits.

### SUMMARY

In one embodiment of the present invention, there is provided a random number generator which has a) a noise source configured to generate M noise bits, and b) an entropy enhancement component (EEC) configured to receive an input sequence of the M noise bits, process the input sequence of the noise bits, and output a random sequence of bits, wherein the random sequence of bits is more random than the input sequence of the noise bits.

In one embodiment of the present invention, there is provided a method for generating random numbers from M noise sources. The method inputs a sequence of M noise bits into an entropy enhancement component (EEC); outputs a random sequence of bits from the EEC which is more random than the input sequence of the noise bits.

Additional aspects of the present invention will become apparent from the following description.

### BRIEF DESCRIPTION OF THE DRAWINGS

FIG. 1 is a block diagram of an entropy source in accordance with one embodiment of the present invention;

FIG. 2 is a block diagram of random number generator in accordance with one embodiment of the present invention;

FIG. 3 is a graph depicting a probability of entropy drop as a function of the number of noise sources in accordance with still another embodiment of the present invention;

FIG. 4 is a block diagram of a specific random number generator in accordance with yet another embodiment of the present invention;

FIG. 5 is a block diagram of another specific random number generator in accordance with still yet a further embodiment of the present invention; and

FIG. 6 is a flowchart illustrating a method for generating a random number sequence in accordance with another embodiment of the present invention.

### DETAILED DESCRIPTION

Various embodiments are described below in more detail with reference to the accompanying drawings. The present invention may, however, be embodied in different forms and thus should not be construed as limited to the embodiments set forth herein. Rather, these embodiments are provided so that this disclosure is thorough and complete and fully conveys the scope of the present invention to those skilled in the art. Moreover, reference herein to “an embodiment,” “another embodiment,” or the like is not necessarily to only one embodiment, and different references to any such phrase are not necessarily to the same embodiment(s). Throughout the disclosure, like reference numerals refer to like parts in the figures and embodiments of the present invention.

The invention can be implemented in numerous ways, including as a process; an apparatus; a system; a computer program product embodied on a computer-readable storage medium; and/or a processor, such as a processor suitable for executing instructions stored on and/or provided by a memory coupled to the processor. In this specification, these implementations, or any other form that the invention may take, may be referred to as techniques. In general, the order of the steps of disclosed processes may be altered within the scope of the invention. Unless stated otherwise, a component such as a processor or a memory described as being suitable for performing a task may be implemented as a general component that is temporarily configured to perform the task at a given time or a specific component that is manufactured to perform the task. As used herein, the term ‘processor’ or the like refers to one or more devices, circuits, and/or processing cores suitable for processing data, such as computer program instructions.

A detailed description of embodiments of the invention is provided below along with accompanying figures that illustrate aspects of the invention. The invention is described in connection with such embodiments, but the invention is not limited to any embodiment. The scope of the invention is limited only by the claims. The invention encompasses numerous alternatives, modifications and equivalents within the scope of the claims. Numerous specific details are set forth 20) in the following description in order to provide a thorough understanding of the invention. These details are provided for the purpose of example; the invention may be practiced according to the claims without some or all of these specific details. For clarity, technical material that is known in technical fields related to the invention has not been described in detail so that the invention is not unnecessarily obscured.

As seen from the background material, an Entropy Source (ES) is a key component for True Random Number Generator (TRNG). According to NIST, an Entropy source contains two basic elements, i.e., a Noise Source (NS), which generates basic necessary entropy in order to produce true random numbers, and a Conditioning Component (CC), which enhances entropy provided by NS. As a result, ES produces random numbers with much higher entropy than initially provided by the NS.

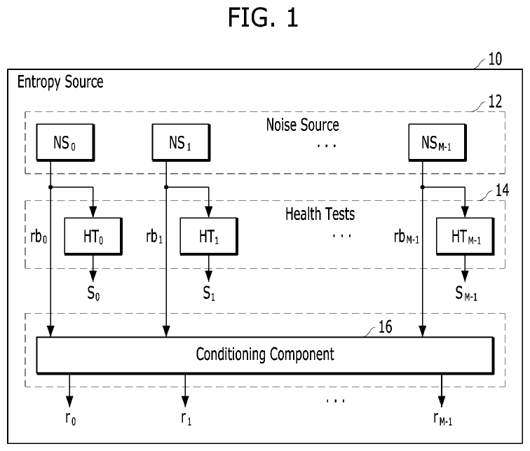

An ES may have multiple NSs coupled with multiple Health Test (HT) blocks. Indeed, as shown in FIG. 1 (which is a general block diagram of an M-output entropy source), an entropy source 10 contains three basic components (noise source 12, health test blocks 14, conditioning component 16). The entropy source 10 shown in FIG. 1 has M independent noise sources (NSi, 0≤i≤ M−1) followed by M health tests blocks (HTi, 0≤i≤ M−1) and the conditioning component 16. Each NSi produces random bits rbi which are fed into a corresponding HTi block. In general, random bits are processed by the conditioning component 16 in order to achieve better statistical characteristics of the processed sequences on outputs of r0, r1, . . . , rM−1, such as for example performing an exclusive OR (XOR) operation of the random bits rbi with the Pseudorandom Number Generator (PRNG) outputs which are uniformly distributed. As a result, changing the distribution of 1s and 0s in the data stream to be more equal.

More specifically, each HT block generates a response si (0≤i≤M−1, where M represents number of channels (NSs)), which indicates that NSi passed the necessary health test (si=0) or failed to pass it (si=1). The NIST standard does not state how to decide whether the whole ES passed health tests if some of the channels passed the tests and some of the channels did not. Therefore, additional memory is used to store ‘health’ bits from channels passed the tests.

As a result of having NSs, which are not passing health tests, the entropy of random numbers generated by ES after conditioning by CC 16 significantly decreases. In one embodiment of the present invention, a novel processing method enhances the consistency of ES, which leads to having the same entropy or having a minor (e.g., 1-2%) entropy decrease even under conditions where individual noise sources fail the health tests.

### Inventive Processing

In one embodiment of the present invention, the inventive processing occurs with an additional component, which pre-processes the random data from the NSs before sending the random data to CC 16. This pre-processing provides a better randomized uniformity of zeros and ones than from the NSs 12. This pre-processing can be provided by different ways (e.g., scrambling, von Neumann corrector, or exclusive OR (XOR) based approaches, etc.).

Experimental results by the inventors have shown that the initial entropy level ˜0.9 (the entropy value is accessed according to NIST standard SP800-90B. and the maximal value is 1.0) can significantly drop to ˜0.1 when the number of NS channels passing health tests is small (e.g., 1-3 out of 8 which is less than 30%). By the inventive processing, the inventors have found out that a stable or an insignificantly reduced entropy (1-2% drop) output is possible remarkably even if only one of the NSs passes the health test.

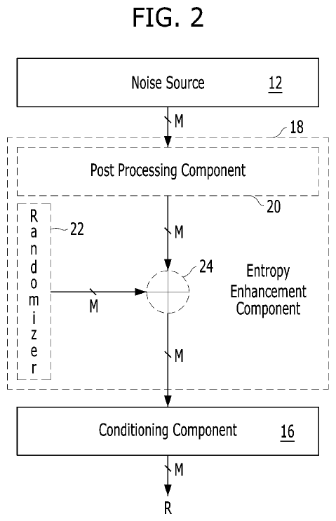

FIG. 2 is a block diagram of one embodiment of the inventive noise source of the present invention. Here, a standard entropy source (e.g., NS 12) with a conditioning component (CC) 16 further includes an entropy enhancement component (EEC) 18, as shown in FIG. 2.

EEC 18 may have three optional parts, i.e., a post processing component 20, a randomizer 22, and a set of XOR gates 24). All the elements can be used in different combinations, e.g., only post processing component 20 or randomizer 22 and XOR gates 24, or all three components together, etc.

NS 12 generates M random bits that are processed by EEC 18 and which are further sent to CC 16, which generates M bits by default. The present invention is not limited to M bits and may generate a number of bits greater than M.

### Working Examples

In one example, eight (8) identical NSs and a CC converting 8-bit input to 128-bit output have been implemented in a Xilinx Artix-7 field programmable array (FPGA). The failure of a noise source was simulated by generating a constant zero during the whole experimental run. For each number of active NSs (1≤k≤8), there have combinations tested. The initial entropy of NS is ˜0.6 and after CC it increases to ˜0.9. During some experimental runs, the entropy level remained the same (˜0.9), and in some runs the entropy level dropped to lower values (˜0.1). Each experimental run was repeated five times. Thus, number of experimental runs for each number of active NSs (k) is 5×(⁸ₖ). The experimental results are shown in Table 1, which shows the probability of maintaining high entropy for different combinations of active NSs.

TABLE 1

| # of active NSs | 1 | 2 | 3 | 4 | 5 | 6 | 7 | 8 |
|---|---|---|---|---|---|---|---|---|
| # of combinations | 40 | 140 | 280 | 350 | 280 | 140 | 40 | 5 |
| # of runs with high entropy (~0.9) | 20 | 104 | 240 | 319 | 263 | 137 | 39 | 5 |
| # of runs with low entropy (~0.1) | 20 | 36 | 40 | 31 | 17 | 3 | 1 | 0 |
| Probability of entropy drop | 0.500 | 0.257 | 0.143 | 0.089 | 0.061 | 0.021 | 0.025 | 0.000 |

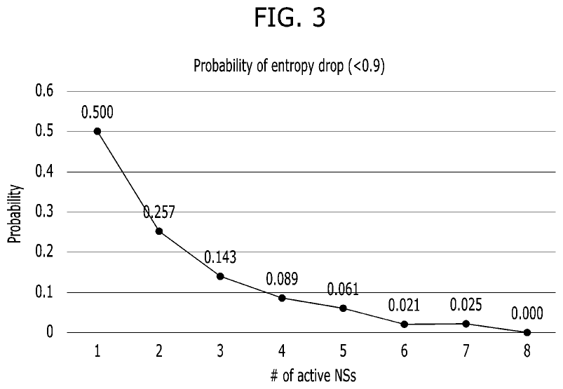

The dependency of the probability of entropy drop is shown in FIG. 3, which shows the probability of entropy drop depending on a number of active NSs. Remarkably, even with the failure of one noise source during the whole experimental run there is a non-zero probability of entropy drop. The only case when entropy drop is not observed (the probability is 0.000) when all eight noise sources are active (not in failure).

In this working example, each experiment was repeated with two different EEC configurations, namely T Flip-Flop (TFF) based or linear feedback shift register (LFSR) based.

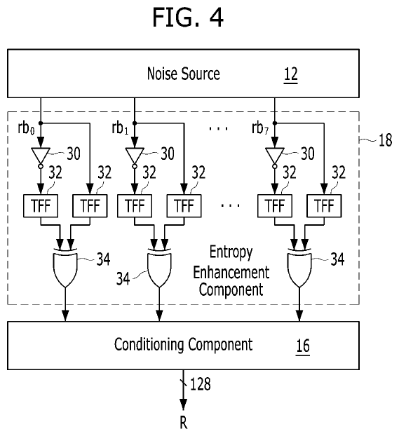

The first EEC configuration is shown in FIG. 4 showing an EEC 18 based on TFF. In this configuration, EEC 18 has M=8 sub blocks each containing one inverter 30, two T-type synchronous Flip-Flops 32, and a two-input XOR gate 34. This EEC 18 shown in FIG. 4 corresponds to a scheme with a post processing component 20 made of inverter 30, Flip-Flops 32, and XOR gate 34 (without a set of XOR gates 24 processing the outputs from the two-input XOR gates 34). In this embodiment, if a noise source “is stuck” in zero or one value (as in the working example), the sub block (i.e., EEC 18) generates a sequence 0, 1, 0, 1, . . . as long as a NS does not pass health tests. The experimental results shown in Table 1 demonstrate that for all cases remarkably the probability of an entropy drop is 0.0, i.e., that entropy value does not reduce lower than 0.9.

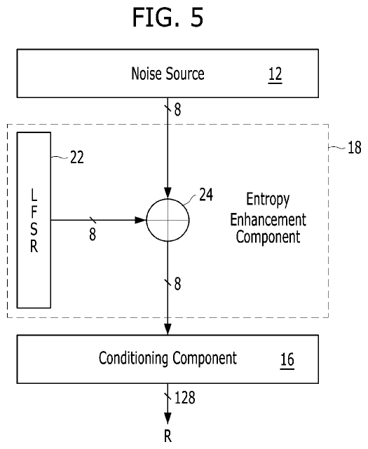

The second EEC configuration is shown in FIG. 5 showing an EEC 18 based on LFSR 22. In this configuration, LFSR 22 is synchronized with the bits from the noise sources using a system clock signal. In this configuration, each noise source itself can generate random bits asynchronously on demand by a request signal. In this configuration, EEC 18 corresponds to a scheme in which LFSR 22 serves as a randomizer and in which a set of XOR gates 24 processes outputs from LFSR 22 and the NSs 12, without the necessity of any post processing component 20. This variant of the inventive EEC 18 improves or guarantees that the outputs of XOR gates 24 will be uniformly distributed, i.e., number of ones is approximately the same as the number of zeros generated. Similarly, to the TFF based EEC configuration, the experimental results demonstrate that for all cases the probability of entropy drop is also 0.0, i.e., the entropy value is always not less than 0.9.

A hardware overhead comparison for the true random number generators (TRNG) is given in Table 2

TABLE 2

| | |
|---|---|
| | Percentage of |
| Circuit | TRNG Overhead, % |

| TRNG Component | LUTs | FFs | LUTs | FFs |
|---|---|---|---|---|
| NS | 8 | 8 | 2.3 | 5.9 |
| CC | 335 | 128 | 97.7 | 94.1 |
| TRNG (NS + CC) | 343 | 136 | 100.0 | 100.0 |
| TFF based EEC | 16 | 16 | 4.6 | 11.7 |
| LFSR based EEC | 10 | 8 | 2.9 | 5.9 |

As shown in Table 2, where LUTs are the number of look up tables and FFs are the number of flip-flops, the LFSR based EEC configuration occupies less area but requires a seed for LFSR operation. In one embodiment, the seed is not synchronized with the noise source, and may be generated in different ways, e.g., be a constant or be updated by random bits from the noise source from time to time. As shown in Table 2, both the EEC configurations require less than 10% of the whole TRNG additional hardware overhead, which is acceptable to prevent entropy drops even in a case that only one of NSs operates normally.

### Operational Method

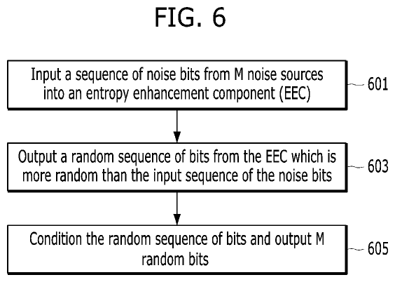

FIG. 6 is a flowchart illustrating a method for generating a random number sequence. The method at 601 inputs a sequence of noise bits from M noise sources into an entropy enhancement component (EEC). At 603, the method outputs a random sequence of bits from the EEC which is more random than the input sequence of the noise bits. At optional 605, the method may condition the random sequence of bits and outputs M random bits.

The method of FIG. 6 may further comprise health-testing the input sequence of the noise bits from the M noise sources. The method of FIG. 6 may further comprise maintaining entropy when only one of the noise sources passes health-testing.

The method of FIG. 6 may output for the random sequence of bits a sequence of the noise bits having “1s” and “0s” uniformly distributed within the output sequence. In one embodiment, the random sequence of bits has a number of ones which is approximately equal to a number of zeros.

With the method of FIG. 6, the EEC may comprise at least one of a) a post processing component configured to process the input sequence of the noise bits, b) a randomizer, and c) a set of exclusive-OR gates. More specifically, in this method, the EEC may comprise a post processing component including a set of inverters receiving the input sequence of the noise bits from the M noise sources, a set of T-type synchronous flip-flops, and a set of two-input XOR gates. In another embodiment, the EEC may comprise a linear feedback shift register configured to generate a random sequence of bits, and an exclusive-OR gate.

The method of FIG. 6 may further maintain an entropy drop and keep the entropy value not less than 0.9 even when one of the noise sources fail health-testing.

In another embodiment of the invention, there is provided a random number generator such as shown for example in FIGS. 2, 4, and 5 which has a) a noise source configured to generate M sources of noise bits, b) an entropy enhancement component (EEC) configured to receive an input sequence of the noise bits from the M sources, process the input sequence of the noise bits, and output a random sequence of bits, wherein the random sequence of bits is more random than the input sequence of the noise bits, and optionally c) a conditioning component configured to condition the random sequence of the bits and output M random bits.

The random number generator may have a set of heath tests blocks configured to health-test the input sequence of the M noise bits from the M noise sources, and the EEC may be configured to maintain entropy even when only one of the noise sources passes health-testing. The output sequence of the noise bits from the EEC may have “1s” and “0s” uniformly distributed within the output sequence. In the output sequence, a number of ones can be approximately equal to a number of zeros.

In the random number generator, the EEC may comprise at least one of a) a post processing component configured to process the input sequence of the noise bits, b) a randomizer, and c) a set of exclusive-OR gates.

In the random number generator, the EEC may comprise a post processing component (such as shown in FIG. 4) including a set of inverters receiving the input sequence of the noise bits from the M noise sources, a set of T-type synchronous flip-flops, and a set of two-input XOR gates. For a pair of the T-type synchronous flip-flops, a first flip-flop of the pair may receive input from one of the inverters and a second flip-flop of the pair may receive input from one of the noise bits. In this embodiment, each two-input XOR gate may receive outputs from the pair of the T-type synchronous flip-flops

In the random number generator, the EEC may comprise (such as shown in FIG. 5) for each M noise source a linear feedback shift register configured to generate a pseudorandom sequence of bits, and an exclusive-OR gate. The exclusive-OR gate may receive one of the noise bits from the M noise sources and the exclusive-OR gate may process the received noise bit from the M noise sources to one of the pseudorandom sequence of bits from the linear feedback shift register.

Although the foregoing embodiments have been illustrated and described in some detail for purposes of clarity and understanding, the present invention is not limited to the details provided. There are many alternative ways of implementing the invention, as one skilled in the art will appreciate in light of the foregoing disclosure. The disclosed embodiments are thus illustrative, not restrictive. The present invention is intended to embrace all modifications and alternatives recognized by one skilled in the art.

Implementations of the subject matter and the functional operations described in this patent document can be implemented in various systems, digital electronic circuitry, or in computer software, firmware, or hardware, including the structures disclosed in this specification and their structural equivalents, or in combinations of one or more of them. Implementations of the subject matter described in this specification can be implemented as one or more computer program products, i.e., one or more modules of computer program instructions encoded on a tangible and non-transitory computer readable medium for execution by, or to control the operation of, data processing apparatus. The computer readable medium can be a machine-readable storage device, a machine-readable storage substrate, a memory device, or a combination of one or more of them. Apparatus, devices, and machines for processing data in the invention can include, in addition to hardware, code that creates an execution environment for the computer program in question, e.g., code that constitutes processor firmware, a protocol stack, a database management system, an operating system, or a combination of one or more of them.

A computer program (also known as a program, software, software application, script, or code) can be written in any form of programming language, including compiled or interpreted languages, and it can be deployed in any form, including as a stand-alone program or as a module, component, subroutine, or other unit suitable for use in a computing environment. A computer program does not necessarily correspond to a file in a file system. A program can be stored in a portion of a file that holds other programs or data (e.g., one or more scripts stored in a markup language document), in a single file dedicated to the program in question, or in multiple coordinated files (e.g., files that store one or more modules, sub programs, or portions of code). A computer program can be deployed to be executed on one computer or on multiple computers that are located at one site or distributed across multiple sites and interconnected by a communication network. The computer program can be embodied as a computer program product as noted above containing a computer readable medium.

The processes and logic flows described in this specification can be performed by one or more programmable processors executing one or more computer programs to perform functions by operating on input data and generating output. The processes and logic flows can also be performed by, and apparatus can also be implemented as, special purpose logic circuitry, e.g., an FPGA (field programmable gate array) or an ASIC (application specific integrated circuit).

Processors suitable for the execution of a computer program include, by way of example, both general and special purpose microprocessors, and any one or more processors of any kind of digital computer. Generally, a processor will receive instructions and data from a read only memory or a random access memory or both. The essential elements of a computer are a processor for performing instructions and one or more memory devices for storing instructions and data. Generally, a computer will also include, or be operatively coupled to receive data from or transfer data to, or both, one or more mass storage devices for storing data, e.g., magnetic, magneto optical disks, or optical disks. However, a computer need not have such devices. Computer readable media suitable for storing computer program instructions and data include all forms of non-volatile memory, media and memory devices, including by way of example semiconductor memory devices, e.g., EPROM, EEPROM, and flash memory devices. The processor and the memory can be supplemented by, or incorporated in, special purpose logic circuitry.

While this patent document contains many specifics, these should not be construed as limitations on the scope of any invention or of what may be claimed, but rather as descriptions of features that may be specific to particular embodiments of particular inventions. Certain features that are described in this patent document in the context of separate embodiments can also be implemented in combination in a single embodiment. Conversely, various features that are described in the context of a single embodiment can also be implemented in multiple embodiments separately or in any suitable sub-combination. Moreover, although features may be described above as acting in certain combinations, one or more features from a combination can in some cases be excised from the combination, and the combination may be directed to a sub-combination or variation of a sub-combination.

What is claimed is:

1. A random number generator comprising:
a noise source configured to generate M noise bits; and
an entropy enhancement component (EEC) configured to receive an input sequence of the noise bits from the M sources, process the input sequence of the noise bits, and output a random sequence of bits, wherein the random sequence of bits is more random than the input sequence of the noise bits.

2. The generator of claim 1, further comprising
a conditioning component configured to condition the random sequence of the bits and output M random bits; and
a set of heath tests blocks configured to health-test the input sequence of the noise bits from the M noise sources,
wherein the EEC is configured to maintain entropy even when only one of the noise sources passes health-testing.

3. The generator of claim 1, wherein the output random sequence of bits from the EEC has “1s” and “0s” uniformly distributed within the output sequence.

4. The generator of claim 3, wherein, in the output random sequence, a number of ones is approximately equal to a number of zeros.

5. The generator of claim 1, wherein the EEC comprises at least one of a) a post processing component configured to process the input sequence of the noise bits, b) a randomizer, and c) a set of exclusive-OR gates.

6. The generator of claim 1, wherein the EEC comprises:
a post processing component including a set of inverters receiving the input sequence of the noise bits from the M noise sources, a set of T-type synchronous flip-flops, and a set of two-input XOR gates.

7. The generator of claim 6, wherein, for a pair of the T-type synchronous flip-flops, a first flip-flop of the pair receives input from one of the inverters and a second flip-flop of the pair receives input from one of the noise bits.

8. The generator of claim 7, wherein each two-input XOR gate receives outputs from the pair of the T-type synchronous flip-flops.

9. The generator of claim 1, wherein the EEC comprises:
a linear feedback shift register configured to generate a pseudorandom sequence of bits, and
an exclusive-OR gate.

10. The generator of claim 9, wherein
the exclusive-OR gate receives one of the noise bits from the M noise sources, and
the exclusive-OR gate processes the received noise bit from the M noise sources to one of the pseudorandom sequence of bits from the linear feedback shift register.

11. A method for generating random numbers from M noise sources, comprising:
inputting a sequence of noise bits from the M noise sources into an entropy enhancement component (EEC); and
outputting a random sequence of bits from the EEC which is more random than the input sequence of the noise bits.

12. The method of claim 11, further comprising:
conditioning the random sequence of bits and outputting M random bits; and
health-testing the input sequence of the noise bits from the M noise sources.

13. The method of claim 12, further comprising maintaining entropy when only one of the noise sources passes health-testing.

14. The method of claim 11, wherein the outputting comprises outputting for the random sequence of bits a sequence of the noise bits having “1s” and “0s” uniformly distributed within the output sequence.

15. The method of claim 14, wherein the random sequence of bits has a number of ones is approximately equal to a number of zeros.

16. The method of claim 11, wherein the EEC comprises at least one of a) a post processing component configured to process the input sequence of the M noise bits, b) a randomizer, and c) a set of exclusive-OR gates.

17. The method of claim 11, wherein the EEC comprises:
a post processing component including a set of inverters receiving the input sequence of the noise bits from the M noise sources, a set of T-type synchronous flip-flops, and a set of two-input XOR gates.

18. The method of claim 11, wherein the EEC comprises:
a linear feedback shift register configured to generate a pseudorandom sequence of bits, and
an exclusive-OR gate.

19. The method of claim 16, further comprising maintaining an entropy value not less than 0.9 even when one of the noise sources fail health-testing.

20. A random number generator comprising:
a set of noise sources configured to generate noise bits;
a set of heath tests blocks configured to health-test an input sequence of the noise bits from the noise sources; and
means for maintaining entropy of the noise bits even when only one of the noise sources passes health-testing.
